(19) United States
(12) Patent Application Publication
(10) Pub. No.: US 2026/0170319 A1
(43) Pub. Date: Jun. 18, 2026

(54) MEMRISTOR DEVICES FOR NEUROMORPHIC COMPUTING

(71) Applicant: TetraMem Inc., Fremont, CA (US)

(72) Inventors: Minxian Zhang, Amherst, MA (US); Ning Ge, Danville, CA (US)

(73) Assignee: TetraMem Inc., Fremont, CA (US)

(21) Appl. No.: 18/971,876

(22) Filed: Dec. 6, 2024

(51) Int. Cl. G06N 3/065; H10N 70/00; H10N 70/20

(52) U.S. Cl. CPC G06N 3/065; H10N 70/021; H10N 70/041; H10N 70/063; H10N 70/24; H10N 70/841; H10N 70/8833

(57) ABSTRACT

The present disclosure relates to memristor devices for neuromorphic computing. A memristor device may include a first electrode, a switching oxide layer, and a second electrode fabricated on the interface layer. The first electrode may include a noble metal and/or an inert metal, such as platinum, palladium, iridium, tungsten, molybdenum, ruthenium, etc. The switching oxide layer may include a polycrystalline oxide. The polycrystalline oxide may be a base oxide (e.g., silicon dioxide, hafnium dioxide, tantalum pentoxide, etc.) doped with Cu, CuO, Cu₂O, etc. The second electrode may include one or more metallic materials that may provide metal ions in response to the application of a suitable voltage to the memristor device, such as copper, silver, etc.

### TECHNICAL FIELD

The implementations of the disclosure relate generally to memristor devices and, more specifically, to memristor devices for neuromorphic computing and methods for fabricating the same.

### BACKGROUND

Memristor devices may be used to implement a neural network that emulates synaptic transmission and neuronal functions. Non-volatile memristors maintain their conductance state over time without power, making them ideal for storing weights in the neurons of a neural network. These memristors utilize a filament or local conductive channel enriched with oxygen vacancies, the conductance of which can be precisely tuned and retained through the control of oxygen ion migration. Volatile memristors, on the other hand, exhibit temporary high conductance states that decay over time when the stimulating electric field is removed. This characteristic is due to the migration of metallic ions within the memristor. Volatile memristors may be used to simulate synapses in neuromorphic computing, allowing for transient connections between neurons that mimic the natural communication via neurotransmitters in the brain.

### SUMMARY

The following is a simplified summary of the disclosure to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

According to one or more aspects of the present disclosure, a semiconductor device including at least one memristor device is provided. The memristor device includes a first electrode, a switching oxide layer fabricated on the first electrode, and a second electrode fabricated on the switching oxide layer. The switching oxide layer includes at least one base oxide doped with at least one dopant.

In some embodiments, the base oxide includes at least one of silicon dioxide (SiO₂), hafnium dioxide (HfO₂), tantalum pentoxide (Ta₂O₅), zirconium dioxide (ZrO₂), niobium pentoxide (Nb₂O₅), vanadium pentoxide (V₂O₅), and wherein the at least one dopant includes at least one of copper (Cu), cuprous oxide (Cu₂O), or cupric oxide (CuO).

In some embodiments, the first electrode includes at least one of platinum (Pt), palladium (Pd), iridium (Ir), tungsten (W), molybdenum (Mo), or ruthenium (Ru).

In some embodiments, the second electrode includes at least one of Cu or Ag.

In some embodiments, the memristor device further includes a first interface layer fabricated between the switching oxide layer and the second electrode, wherein the first interface layer includes a first dielectric material, and wherein the first dielectric material includes at least one of Al₂O₃, Y₂O₃, or MgO.

In some embodiments, the first interface layer includes a discontinuous layer of the first dielectric material, and wherein at least a portion of the second electrode is deposited on the switching oxide layer through the discontinuous layer of the first dielectric material.

In some embodiments, the memristor device includes a second interface layer fabricated between the first electrode and the switching oxide layer, wherein the second interface layer includes a second dielectric material.

In some embodiments, the second dielectric material includes at least one of Al2O3, Y2O3, or MgO, and wherein the second interface layer includes a discontinuous layer of the second dielectric material, and wherein at least a portion of the switching oxide layer is deposited on the first electrode through the second interface layer.

In some embodiments, the memristor device further includes a capping layer fabricated on the second electrode, wherein the capping layer includes a metal or a metal nitride.

In some embodiments, the memristor device further includes a layer of tantalum deposited between the first electrode and a substrate.

According to one or more aspects of the present disclosure, a method for fabricating a memristor device is provided. The method includes fabricating, on a first electrode, a switching oxide layer including at least one base oxide doped with at least one dopant; annealing the switching oxide layer; and fabricating a second electrode on the annealed switching oxide layer.

In some embodiments, the base oxide includes at least one of silicon dioxide (SiO₂), hafnium dioxide (HfO₂), tantalum pentoxide (Ta₂O₅), zirconium dioxide (ZrO₂), niobium pentoxide (Nb₂O₅), vanadium pentoxide (V₂O₅), and wherein the at least one dopant includes at least one of copper (Cu), cuprous oxide (Cu₂O), or cupric oxide (CuO).

In some embodiments, the first electrode includes at least one of platinum (Pt), palladium (Pd), iridium (Ir), tungsten (W), molybdenum (Mo), or ruthenium (Ru).

In some embodiments, the second electrode includes a metallic material for providing metal ions during drift switching of the memristor device, wherein the metallic material includes at least one copper (Cu) or silver (Ag).

In some embodiments, the method further includes fabricating a first interface layer positioned between the switching oxide layer and the second electrode, wherein the first interface layer includes a discontinuous layer of a first dielectric material, and wherein fabricating the second electrode includes depositing at least a metallic material on the switching oxide layer through the discontinuous layer of the first dielectric material.

In some embodiments, the method further includes fabricating, on the first electrode, a second interface layer including a second dielectric material, wherein the switching oxide layer is fabricated on the second interface layer.

In some embodiments, the second dielectric material includes at least one of Al₂O₃, Y₂O₃, or MgO, wherein the second interface layer includes a discontinuous layer of the second dielectric material, and wherein at least a portion of the switching oxide layer is deposited on the first electrode through the second interface layer.

In some embodiments, the method further includes fabricating a capping layer on the second electrode, wherein the capping layer includes at least one of a metal or a metal nitride.

In some embodiments, the method further includes depositing a layer of tantalum metal on a substrate, wherein the first electrode is fabricated on the layer of tantalum metal.

In some embodiments, the switching oxide layer is annealed in an environment of argon (Ar) and oxygen (O₂).

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding.

FIGS. 1A, 1B, 1C, 1D, 1E, 1F, and 1G illustrate cross-sectional views of device stacks for fabricating memristor devices in accordance with one implementation of the present disclosure.

FIGS. 2A, 2B, 2C, 2D, 2E, 2F, and 2G illustrate cross-sectional views of device stacks for fabricating memristor devices containing an interface layer in accordance with one implementation of the present disclosure.

FIGS. 3A, 3B, 3C, 3D, 3E, and 3F illustrate device stacks for fabricating memristor devices with multiple interface layers in accordance with some embodiments of the present disclosure.

FIGS. 4A, 4B, and 4C are diagrams illustrating cross-sectional views of device stacks for fabricating semiconductor devices comprising memristor devices in accordance with another implementation of the present disclosure.

FIGS. 5, 6, 7, and 8 are flow diagrams illustrating example processes for fabricating memristor devices in accordance with some embodiments of the present disclosure.

### DETAILED DESCRIPTION

Aspects of the disclosure provide memristor devices and methods for fabricating the memristor devices.

Memristor devices may be used to implement a neural network that emulates synaptic transmission and neuronal functions. Non-volatile memristors maintain their conductance state over time without power, making them ideal for storing weights in the neurons of a neural network. Volatile memristors, on the other hand, exhibit temporary high conductance states that decay over time or when the stimulating electric field is removed. This characteristic is attributed to the migration of metallic ions within the memristor. In particular, such volatile memristors may exhibit synaptic switching behaviors that may involve “on” and “off” switching mechanisms under varying conditions. “On” switching (or drift switching) occurs in the presence of an electric field and involves the formation or strengthening of a conductive path through drifting mechanisms, where electrically driven filament formation occurs. “Off” switching (or diffusive switching), which occurs without an electric field, involves the decay, rupture, or dissolution of this conductive path through diffusive mechanisms, influenced by factors such as chemical gradients, surface tension, etc. The synaptic switching behaviors may be utilized to implement synapses in a neural network.

However, it may be challenging to implement synapses using existing memristor devices due to significant variations in diffusive switching, which may be rooted in inconsistencies in the drift-switching behaviors of these devices. These variations lead to unpredictability in both “On” switching (set voltages) and “Off” switching (decay times), which hinders the reliable emulation of synaptic behavior.

Accordingly, the present disclosure provides volatile memristor devices with consistent synaptic switching behaviors suitable for implementing neuromorphic computing applications. The volatile memristor devices include polycrystalline oxides as switching oxides to reduce synaptic switching variations. Unlike amorphous oxides, polycrystalline oxides may include grain boundaries (e.g., boundaries between a crystalline grain and an amorphous region, or boundaries between two crystalline grains). The grain boundaries in the polycrystalline oxide may act as fast migration paths for metal ions. This may limit the available migration paths for metal ions in the oxide, reduce randomness in ion migration, and reduce variations in synaptic switching. For on-switching, they may help to reduce set voltage variations, while for off-switching, they may reduce decay or relaxation time variations.

Crystallization of amorphous phases of metal oxides in the solid state typically requires substantial energy input to transform the amorphous phase to the crystalline phase. These high-temperature processes are not only costly in energy but may also degrade complex material architectures or compositions. In some embodiments, metal oxide dopants may be used to reduce the oxide crystallization temperatures. Grain boundaries in the switching oxides may reduce switching randomness and switching variations.

In some embodiments, a memristor device may include a first electrode, a switching oxide layer fabricated on the first electrode, an interface layer fabricated on the oxide layer, and a second electrode fabricated on the interface layer. The first electrode may include a noble metal and/or an inert metal, such as platinum (Pt), palladium (Pd), iridium (Ir), tungsten (W), molybdenum (Mo), ruthenium (Ru), etc. The switching oxide layer may include one or more base oxides doped with one or more dopants. The base oxide may include, for example, silicon dioxide (SiO₂), hafnium dioxide (HfO₂), tantalum pentoxide (Ta₂O₅), zirconium dioxide (ZrO₂), niobium pentoxide (Nb₂O₅), vanadium pentoxide (V₂O₅), etc. The dopant(s) may be, for example, copper (Cu), cuprous oxide (Cu₂O), cupric oxide (CuO), etc. The interface layer may include a discontinuous layer of a dielectric material that is more chemically stable than the base oxide, such as aluminum oxide (Al₂O₃), yttrium oxide (Y₂O₃), etc. The second electrode may include one or more metallic materials that may provide metal ions in response to the application of a suitable voltage to the memristor device. In some embodiments, the second electrode may include copper (Cu), silver (Ag), etc. In some embodiments, the memristor device may further include an additional interface layer positioned between the first electrode and the oxide layer. In some embodiments, the memristor device may further include one or more capping layers to prevent the migration of the metal ions outside of the memristor device.

The dopants in the switching oxide layer may act as a catalyst to accelerate the crystallization by reducing the nucleation barriers and promoting the growth of the crystal grains. The dopants may also remove extra Cu ions and oxygen ions in the switching oxide layer to form semiconductive Cu₂O or CuO, which may further eliminate the drift of the Cu-ion and O-ion in the switching oxide layer during the switching and may improve the synaptic switching behavior of the memristor device.

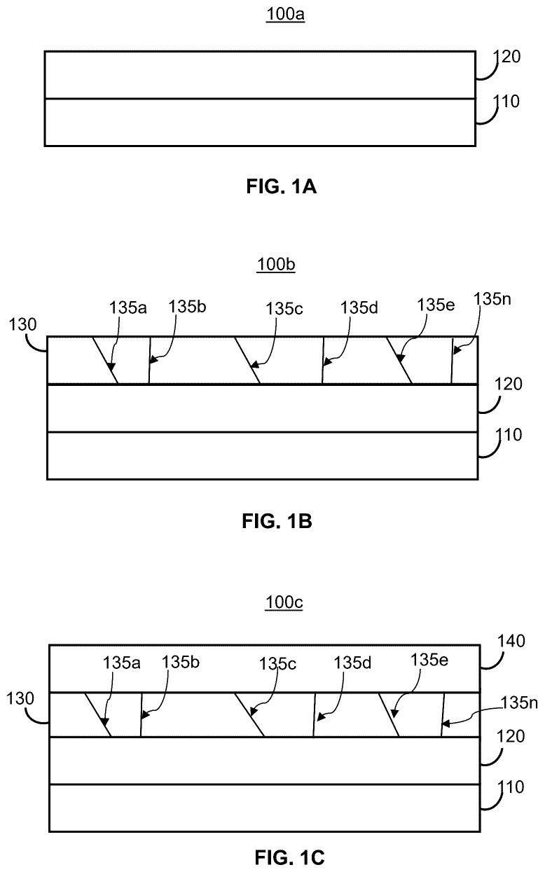

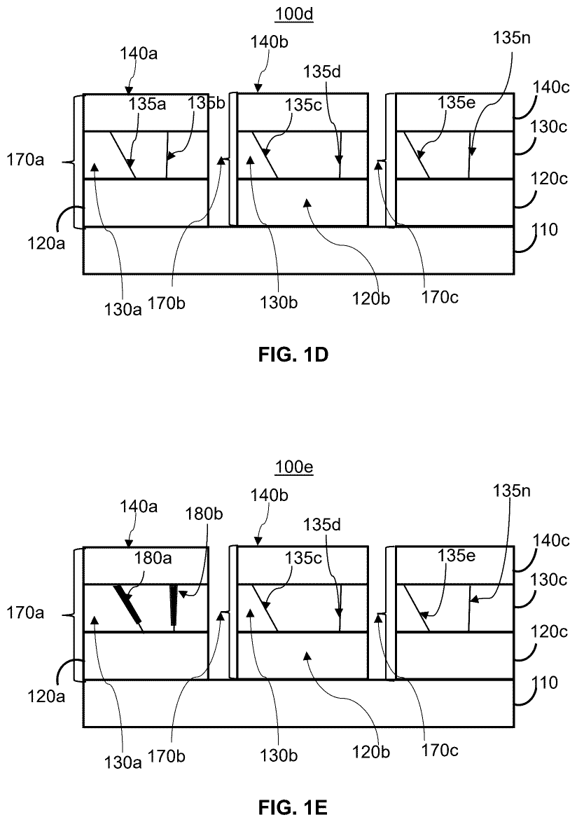

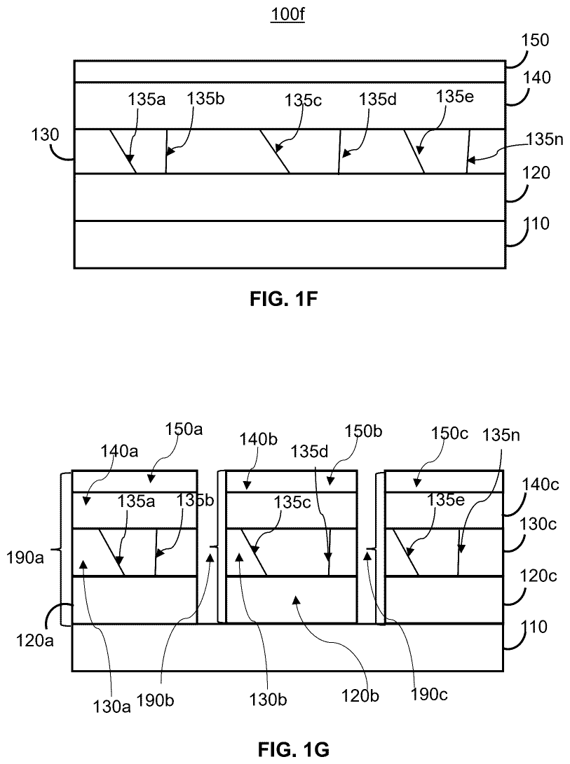

FIGS. 1A, 1B, 1C, 1D, 1E, 1F, and 1G illustrate cross-sectional views of device stacks 100a, 100b, 100c, 100d, 100e, and 100f for fabricating semiconductor devices including memristor devices in accordance with one implementation of the present disclosure.

As shown in FIG. 1A, a substrate 110 may be provided. A first electrode 120 may be fabricated on the substrate 110. The substrate 110 may include one or more layers of any suitable material that may serve as a substrate for an RRAM device, such as silicon (Si), silicon dioxide (SiO₂), silicon nitride (Si₃N₄), aluminum oxide (Al₂O₃), aluminum nitride (AlN), etc. In some embodiments, the substrate 110 may include diodes, transistors, interconnects, integrated circuits, one or more other RRAM devices, etc. In some embodiments, the substrate 110 may include a driving circuit including one or more electrical circuits (e.g., an array of electrical circuits) that may be individually controllable. In some embodiments, the driving circuit may include one or more complementary metal-oxide-semiconductor (CMOS) drivers.

The first electrode 120 may include any suitable material that is electronically conductive and non-reactive to the oxide layer to be fabricated on the first electrode 120 (also referred to as the “non-reactive” material). As an example, the first electrode 120 may include a noble metal and/or an inert metal, such as platinum (Pt), palladium (Pd), iridium (Ir), tungsten (W), molybdenum (Mo), ruthenium (Ru), etc. The first electrode 120 may also be referred to as the “non-reactive electrode.”

Referring to FIG. 1B, a switching oxide layer 130 may be fabricated on the first electrode 120. Switching oxide layer 130 may include one or more switching oxides. Each switching oxide may be a base oxide doped with at least one dopant. Examples of the base oxide may include tantalum pentoxide (Ta₂O₅), hafnium dioxide (HfO₂), zirconium dioxide (ZrO₂), niobium pentoxide (Nb₂O₅), vanadium pentoxide (V₂O₅), or silicon dioxide (SiO₂). The dopant may be one or more of copper (Cu), cuprous oxide (Cu2O), or cupric oxide (CuO). The dopants may act as catalysts to accelerate the crystallization of the base oxide by reducing nucleation barriers and promoting the growth of crystal grains. In some embodiments, the chemical stability of the non-reactive material in the first electrode 120 may be higher than that of the dielectric oxide(s) in oxide layer 130. Unlike certain non-volatile resistive random-access memory (RRAM) that may include oxygen deficiencies intentionally introduced during the fabrication process, the memristor devices described herein include base oxide(s) in stoichiometry or close to stoichiometry of the full oxide.

The dopant (e.g., Cu, Cu₂O, CuO, etc.) may act as a catalyst or promote heterogeneous nucleation to accelerate the crystallization of the base oxide. Cu may be a preferred cation in synaptic switching because it is CMOS compatible, making it more favorable than other candidates for cation (e.g., Ag). Cu oxides are also semiconductors, with Cu₂O (cuprous oxide) having a band gap of 2.51 eV and CuO (cupric oxide) having a band gap of 1.42 eV. The resistivity ratio of Cu₂O to CuO is 3700/16, which equals 231, indicating that the suboxide (Cu₂O) is more resistive than the full oxide (CuO). The dopants Cu, Cu₂O, CuO, etc. may induce the crystallization of base oxide at lower temperatures.

Using Cu₂O and CuO as dopants may also remove extra Cu and/or O ions in the switching oxide layer (e.g., by reacting with excess Cu or O ions present in the switching oxide layer). For example, Cu can react with CuO (a semiconductor) to form Cu₂O, which is also semiconductive. Similarly, Cu₂O may react with oxygen ions to form CuO. Removing extra Cu ions and oxygen ions in the switching oxide layer to form semiconductive Cu₂O or CuO may eliminate the drift of random Cu ions and O ions during switching and may improve the synaptic switching behavior of the switching oxide. The reactions may be represented as follows:

Cu+CuO═Cu₂O

Cu₂O+O=2CuO

The above two chemical reactions illustrate the role of dopants Cu₂O and/or CuO in removing excess Cu ions and/or oxygen ions from the switching oxide. Due to the differing stoichiometry of the dopants Cu₂O, CuO, and the switching oxide (e.g., HfO₂), the dopant concentration may be represented by the ratio of the metal in the dopant to the metal in the switching oxide, i.e., Cu/Hf. In some embodiments, the dopant concentration may be less than 1%. In some embodiments, the dopant concentration may range from 1% to 3%. In yet other embodiments, the dopant concentration may range from 1% to 10%. The switching oxide layer 130 may be annealed at a suitable temperature (e.g., 300° C.-500° C.) for a suitable period of time (e.g., about 15-120 minutes). Annealing the switching oxide layer 130 in a slightly oxidizing environment (e.g., an environment of argon (Ar) and oxygen (O₂)) may convert HfOₓ to HfO₂ and convert Cu to Cu₂O or CuO.

The switching oxide layer 130 may contain Cu-doped switching oxide(s) that are polycrystalline. As shown in FIG. 1B, polycrystalline switching oxide(s) in the switching oxide layer 130 may include grain boundaries 135a, 135b, 135c, 135d, 135e, . . . , 135n. While grain boundaries 135a-n are shown as lines in the cross-sectional view in FIG. 1B, a grain boundary in the switching oxide layer 130 is a two-dimensional plane. The grain boundaries may be boundaries between crystalline grain and amorphous region, or boundaries between two crystalline grains. The grain boundaries in the oxide may act as fast migration paths for metal ions. This may limit the available migration paths for metal ions in the switching oxide layer 130, reduce randomness in ion migration, and reduce variations in synaptic switching. During on-switching, this may reduce set voltage variations, while during off-switching, it may reduce decay or relaxation time variations. While a certain number of grain boundaries are shown in FIG. 1B, this is merely illustrative. The switching oxide layer 130 may include any suitable number of grain boundaries.

Referring to FIG. 1C, a second electrode 140 may be fabricated on the switching oxide layer 130. The second electrode 140 may include any suitable material that is electronically conductive and may function as a source of metal ions during drift switching of the memristor devices to be fabricated. For example, the metallic material in the second electrode 140 may include Cu, Ag, etc. The second electrode 140 may also be referred to herein as an active electrode.

As illustrated in FIG. 1D, the device stack 100c may be patterned and etched to fabricate a plurality of memristor devices 170a, 170b, . . . , 170c. The etching of the first electrode 120 may form first electrodes 120a, 120b, . . . , 120c. The etching of the switching oxide layer 130 may fabricate switching oxide layers 130a, 130b, . . . 130c. The etching of the second electrode 140 may fabricate second electrodes 140a, 140b, . . . , 140c. Each of the memristor devices 170a, 170b, . . . , 170c, may include a first electrode (first electrodes 120a, 120b, . . . , 120c), a switching oxide layer (switching oxide layers 130a, 130b, . . . , 130c), and a second electrode (second electrodes 140a, 140b, . . . , 140c).

As described above, the grain boundaries 135a, 135b, . . . , 135n in the switching oxide layers 130a-130c may act as fast migration paths or less resistive migration paths for metal ions. The grain boundaries may thus limit the available migration paths for metal ions in the switching oxide layer 130a-130c, reduce randomness in ion migration, and reduce variations in synaptic switching. For example, when a suitable voltage is applied to memristor device 170a, metal ions in the second electrode 140a may drift from the second electrode 140a through the switching oxide layer 130a towards the first electrode 120a, forming one or more conductive paths or filaments 180a-180b along the grain boundaries that directly contact the first electrode and the second electrode, as shown in FIG. 1E. As shown, the filaments 180a and 180b are formed along the grain boundaries 135a and 135b (FIG. 1D), respectively. In some embodiments, one or more intermediate layers containing conductive materials (not shown) may be fabricated between the first electrode and the switching oxide layer and/or the second electrode and the switching oxide layer. In such embodiments, the grain boundaries 135a and 135b may contact the first electrode and the second electrode through the conductive materials. This process may also be referred to as “drift switching.” Due to the presence of the grain boundaries 135a-135b, the drift switching may occur at specific locations in the switching oxide layer 130 corresponding to the locations of the grain boundaries 135a-135b.

In some embodiments, as shown in FIG. 1F, a capping layer 150 may be fabricated on the second electrode 140 to form a device stack 100f. The capping layer 150 may include any suitable metallic material that may limit the migration of metal ions from the second electrode 140 to components outside the memristor device. In some embodiments, the capping metal layer 150 may include tantalum (Ta), tantalum nitride (TaN), tungsten (W), tungsten nitride (WN), etc.

Referring to FIG. 1G, the device stack 100f may be patterned and etched to fabricate a plurality of memristor devices 190a, 190b, . . . , 190c. The etching of the first electrode 120 may form first electrodes 120a, 120b, . . . , 120c. The etching of the switching oxide layer 130 may fabricate switching oxide layers 130a, 130b, . . . 130c. The etching of the second electrode 140 may fabricate second electrodes 140a, 140b, . . . , 140c. The etching of the capping layer 150 may fabricate capping layers 150a, 150b, . . . , 150c. Each of the memristor devices 190a, 190b, . . . , 190c, may include a first electrode (first electrodes 120a, 120b, . . . , 120c), a switching oxide layer (switching oxide layers 130a, 130b, . . . , 130c), a second electrode (second electrodes 140a, 140b, . . . , 140c), and a capping layer (capping layers 150a, 150b, . . . , 150c).

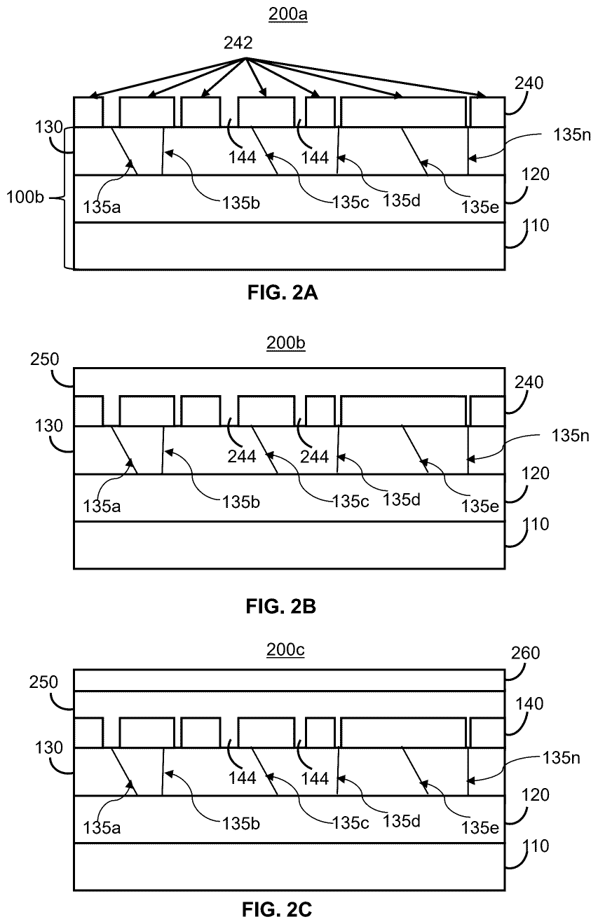

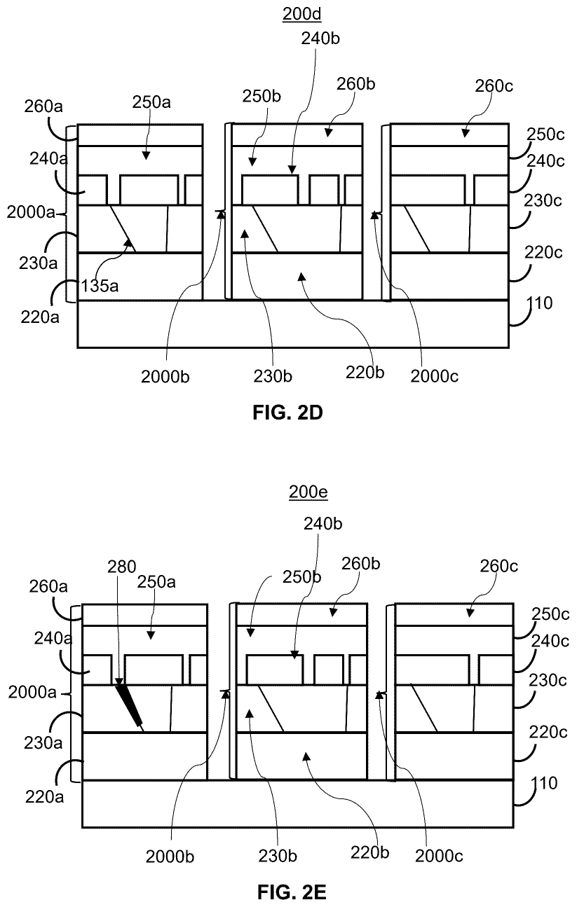

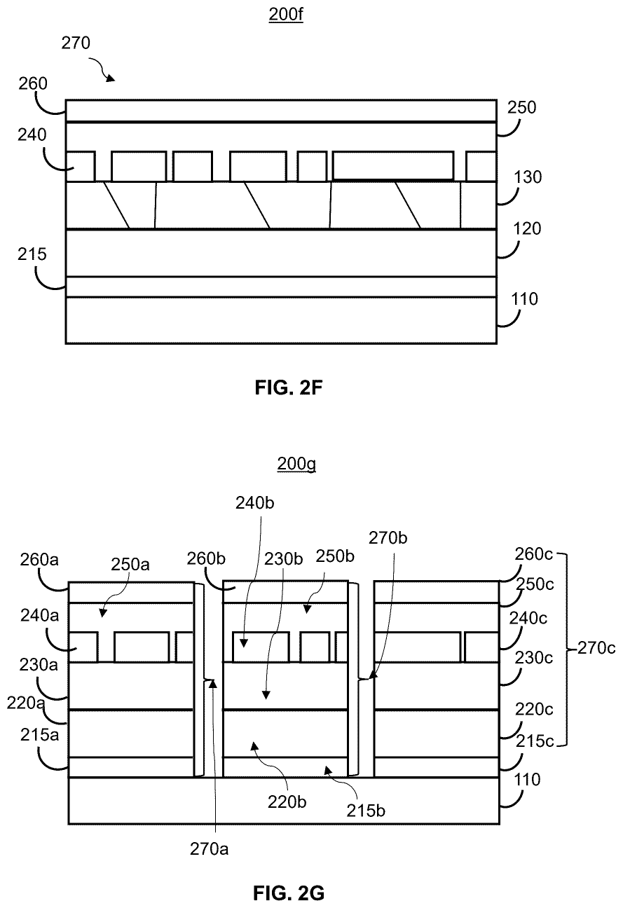

FIGS. 2A, 2B, 2C, 2D, 2E, 2F, and 2G illustrate cross-sectional views of device stacks 200a, 200b, 200c, 200d, 200e, 200f, and 200g for fabricating semiconductor devices incorporating memristor devices containing an interface layer in accordance with one implementation of the present disclosure.

As shown in FIG. 2A, an interface layer 240 may be fabricated on the switching oxide layer 130. The interface layer 240 may be a dielectric material (also referred to as the “first dielectric material”) that is more chemically stable than the base oxide(s) in the switching oxide layer and the electrode materials in the electrodes of the memristor device to be fabricated. As a result, the dielectric material will not react with the dielectric oxide or the electrode materials. Examples of the first dielectric material include Al₂O₃, Y₂O₃, MgO, etc.

As shown, the interface layer 240 may include a discontinuous film 242 of the dielectric material (e.g., islands of the dielectric material) with pores and/or pin-holes 144. The pores and/or pin-holes 144 may be randomly dispersed in the interface layer 240. While a certain number of pores are illustrated in FIG. 2A, this is merely illustrative. The interface layer 140 may include any suitable number of pores and/or pin-holes. In some embodiments, a thickness of the interface layer 240 and/or the discontinuous film 242 may be between about 0.2 nm and about 0.5 nm. In some embodiments, the discontinuous film 242 may be an Al₂O₃ film having a thickness equal to or less than 0.5 nm. In some embodiments, the discontinuous film 242 may be and/or include an Al₂O₃ film having a thickness of less than 1 nm.

As referred to herein, a layer may be regarded as being a discontinuous layer if the layer covers some, but not all, portions of the layer underneath. The discontinuous film 242 of the dielectric material may be fabricated by depositing the dielectric material to a suitable thickness, i.e., a layer that is not thick enough to form a continuous layer of the dielectric layer. In some embodiments, the thickness of the interface layer and/or the discontinuous film of the dielectric material may be approximately on the order of magnitude of the diameter of a single atom or molecule of the dielectric material. In some embodiments, a thickness of the interface layer 240 may be between about 0.2 nm and about 0.5 nm. In some embodiments, a thickness of the interface layer 240 may be about 0.3 nm. As a more particular example, the thickness of an Al₂O₃ monolayer is estimated to be more than the diameter of an Al ion plus the diameter of an oxygen ion, where the diameter of an oxygen ion is 0.252 nm; the diameter of an Al³⁺ ionic is 0.136 nm; and the size of an AlO ion pair is 0.388 nm. As such, an Al₂O₃ layer may be discontinuous when the thickness of the Al₂O₃ film is less than about 0.4 nm. As another more particular example, the diameter of a Si⁴⁺ ion is 0.108 nm; the size of an Si—O ionic pair is 0.360 nm. Thus, a complete SiO₂ monolayer is often not formed, if the thickness of a deposited SiO₂ layer is less than 0.4 nm. In some embodiments, even when the thickness of a deposited film is thicker than 0.4 nm, a dielectric film may still be non-continuous due to the surface energy (or wettability) between the dielectric film and the first electrode.

Since a grain boundary in the switching oxide layer 130 is a two-dimensional plane, one or more of the pinholes in the discontinuous interface layer 240 may contact the grain boundaries, which may further restrict the available sites for Cu-ion migration as described in greater detail below.

Referring to FIG. 2B, a second electrode 250 may be fabricated on the interface layer 240. The second electrode 250 may include any suitable material that is electronically conductive and may function as a source of metal ions during drift switching of the memristor devices to be fabricated. For example, the metallic material in the second electrode 250 may include Cu, Ag, etc. The second electrode 250 may also be referred to herein as an active electrode. The metallic material may be deposited on the top surface of the discontinuous film of the dielectric material and the top surface of the switching oxide layer 130. One or more portions of the second electrode 250 may be deposited on the discontinuous film 242 of the dielectric material and one or more portions of the second electrode 250 may be deposited on the oxide layer 130 through the pores and/or pin-holes 244. As such, at least a portion of the second electrode 250 may be in direct contact with the switching oxide layer 130 through the interface layer 240 (e.g., through the pores and/or pin-holes 244).

In some embodiments, as shown in FIG. 2C, a capping layer 260 may be fabricated on the second electrode 250 to form a device stack 200c. The capping layer 260 may include any suitable metallic material that may limit the migration of metal ions from the second electrode 250 to components outside the memristor device. In some embodiments, the capping metal layer 260 may include tantalum (Ta), tantalum nitride (TaN), tungsten (W), tungsten nitride (WN), etc.

In some embodiments, non-volatile resistive random-access memory (RRAM) (not shown) may be fabricated beneath the first electrode 120 and/or above the second electrode 250 for implementing a neuron network.

Referring to FIG. 2D, the device stack 200c may be patterned and etched to fabricate a plurality of memristor devices 2000a, 2000b, . . . , 2000c. The etching of the first electrode 120 may form first electrodes 220a, 220b, . . . , 220c. The etching of the switching oxide layer 130 may fabricate switching oxide layers 230a, 230b, . . . 230c. The etching of the interface layer 240 may fabricate interface layers 240a, 240b, . . . , 240c. The etching of the second electrode 250 may fabricate second electrodes 250a, 250b, . . . , 250c. The etching of the capping layer 260 may fabricate capping layers 260a, 260b, . . . , 260c. Each of the memristor devices 2000a, 2000b, . . . , 2000c may include a first electrode (first electrodes 220a, 220b, . . . , 220c), a switching oxide layer (switching oxide layers 230a, 230b, . . . , 230c), a second electrode (second electrodes 250a, 250b, . . . , 250c), and an interface layer (interface layers 240a, 240b, . . . , 240c) positioned between the switching oxide layer and the second electrode. Each of the memristor devices 2000a, 2000b, . . . , 2000c may further include a capping layer (capping layers 260a, 260b, . . . , 260c).

When a suitable voltage is applied to a memristor device 2000a, metal ions in the second electrode 250a may drift from the second electrode 250a through the switching oxide layer 230a towards the first electrode 220a, forming one or more conductive paths or filaments 280 along the grain boundaries that directly contact the first electrode 220a and the second electrode 250a, as shown in FIG. 2E. This process may also be referred to as “drift switching.” Due to the presence of the interface layer 240a, the drift switching may occur at specific locations where the second electrode 250a is in direct contact with the switching oxide layer 230a, that is, the locations where the pin-holes in the interface layer directly contact a grain boundary in the switching oxide layer. As such, filaments 280 can only form at the locations where the pin-holes in the interface layer directly contact a grain boundary in the switching oxide layer. The incorporation of the interface layer may thus focus the electric field to specific locations within the device, reduce randomness in the drift switching, and minimize variations in filament location, size, or shape. As a result, cycle-to-cycle switch variations may be reduced, leading to more consistent synaptic switching.

Referring to FIG. 2F, a layer 215 of tantalum (Ta) metal may be fabricated between the first electrode 120 and the substrate 110 in some embodiments. A device stack 270 as shown in FIG. 2F may include the layer 215 of Ta metal, the first electrode 120, the switching oxide layer 130, the interface layer 240, the second electrode 250, and the capping layer 260. Layer 215 may function as an adhesion layer as well as a capping layer to prevent active metal ions (e.g., Cu ions, Ag ions, etc.) from migrating outside the memristor device.

Referring to FIG. 2G, the device stack 270 may be patterned and etched to fabricate a plurality of memristor devices 270a, 270b, . . . , 270c. Each of the memristor devices may include a layer of Ta metal (e.g., layer 215a, 215b, . . . , 215c), a first electrode (e.g., electrode 220a, 220b, . . . , 220c), a switching oxide layer (e.g., switching oxide layer 230a, 230b, . . . , 230c), an interface layer (e.g., interface layers 240a, 240b, . . . , 240c), a second electrode (e.g., electrode 250a, 250b, . . . , 250c), and a capping layer (e.g., capping layer 260a, 260b, . . . , 260c).

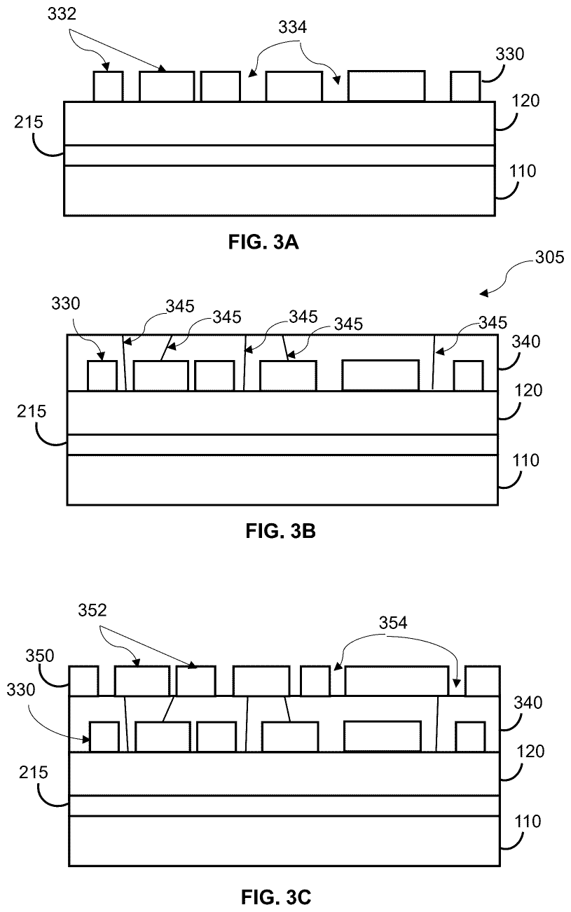

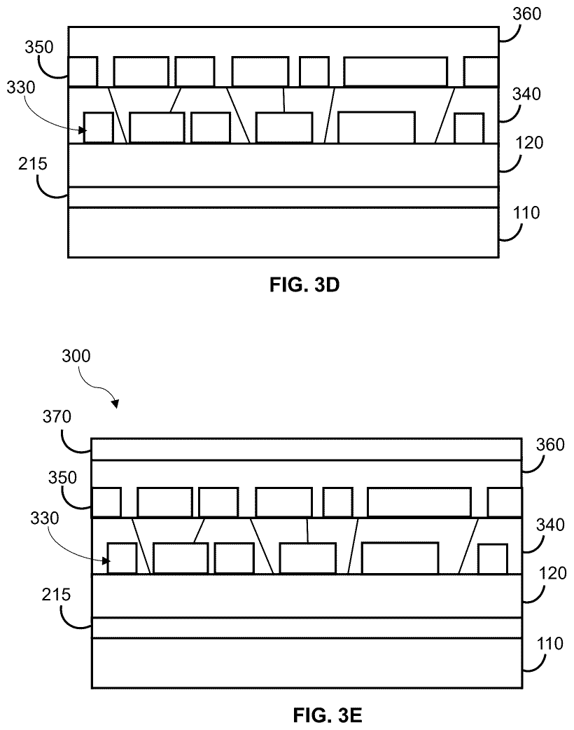

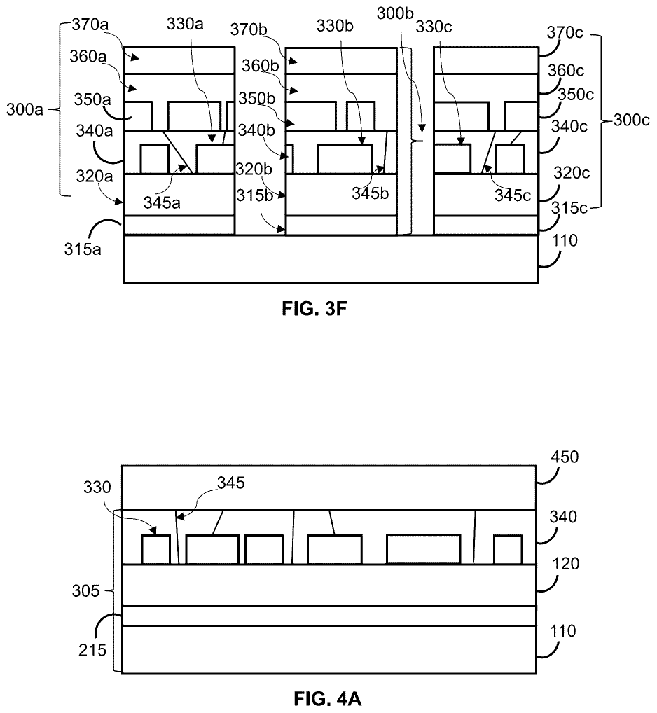

FIGS. 3A, 3B, 3C, 3D, 3E, and 3F illustrate device stacks for fabricating memristor devices with multiple interface layers in accordance with some embodiments of the present disclosure.

As illustrated in FIG. 3A, an interface layer 330 (also referred to as the “interface layer ILA”) may be fabricated on the first electrode 120. In some embodiments, the interface layer 330 may include a discontinuous film 332 of a dielectric material (also referred to as the “second dielectric material”) with pores and/or pin-holes 334. The second dielectric material may be more chemically stable than the dielectric oxide in the oxide layer to be fabricated on the interface layer 330. As an example, the second dielectric material may include Al₂O₃, MgO, Y₂O₃, etc.

As shown, the interface layer ILA may include a discontinuous film 332 of the second dielectric material (e.g., islands of the second dielectric material) with one or more pores and/or pin-holes 334 (also referred to as the “one or more second pores and/or pin-holes”). The pore(s) 334 may have any suitable size and/or dimension. Multiple pores 334 may or may not have the same size and/or dimension. The pores and/or pin-holes 334 may be dispersed randomly in the interface layer 330.

In some embodiments, a thickness of the interface layer 330 and/or the second discontinuous film (also referred to as the “second thickness”) may be between about 0.2 nm and about 0.5 nm. As another example, the interface layer 330 may include a discontinuous Al₂O₃ film having a thickness equal to or less than 0.5 nm. In some embodiments, the second interface layer 330 may include a discontinuous Al₂O₃ film having a thickness less than 1 nm.

As shown in FIG. 3B, a switching oxide layer 340 may be fabricated on the interface layer 330 and the first electrode 120. The switching oxide layer 340 may include one or more switching oxides. Each switching oxide may be a base oxide doped with at least one dopant. Examples of the base oxide may include Ta₂O₅, HfO₂, ZrO₂, Nb₂O₅, V₂O₅, SiO₂, etc. The dopant may be Cu, Cu₂O, CuO, etc. In some embodiments, the chemical stability of the interface layer ILA is higher than that of the non-reactive material in the first electrode 120 and that of the base oxides in the switching oxide layer 340. One or portions of the switching oxide layer 340 may be fabricated on the discontinuous film of the second dielectric material. At least a portion of the switching oxide layer 340 may be directly deposited on the first electrode 120 through the interface layer 330 (e.g., through the pores and/or pin-holes 334). The switching oxide layer 340 may include Cu-doped switching oxide(s) that are polycrystalline. As shown in FIG. 3B, polycrystalline switching oxide(s) in the switching oxide layer 340 may include grain boundaries 345. One or more of the grain boundaries 345 may directly contact the first electrode 120.

As shown in FIG. 3C, an interface layer 350 (also referred to as the “interface layer ILB”) may be fabricated on the switching oxide layer 340. The interface layer 350 may include a discontinuous film 352 of a dielectric material (the first dielectric material) with pores and/or pin-holes 354. The dielectric material of the interface layer ILB may be more chemically stable than the dielectric oxide in the switching oxide layer 340 and the electrode materials in the electrodes of the memristor devices to be fabricated. As a result, the second dielectric material will not react with the dielectric oxide or the electrode materials. Examples of the dielectric material include Al₂O₃, Y₂O₃, MgO, etc.

As shown in FIG. 3D, a second electrode 360 may be fabricated on the switching oxide layer 340 and the interface layer 350. The second electrode 360 may include any suitable material that is electronically conductive and may function as a source of metal ions during drift switching of the memristor devices to be fabricated. For example, the metallic material in the second electrode 360 may include Cu, Ag, etc. The second electrode 360 may also be referred to herein as an active electrode. As the interface layer ILB includes a discontinuous layer of the second dielectric material, at least a portion of the second electrode 360 may be deposited on the switching oxide layer 340 through the interface layer ILB (e.g., through the pinholes in the discontinuous layer of the second dielectric material).

As shown in FIG. 3E, a capping layer 370 may be fabricated on the second electrode 360 to form a device stack 300. The capping layer 370 may include any suitable metallic material that may limit the migration of metal ions outside the memristor device. In some embodiments, the capping layer 370 may include Ta metal, TaN, W, WN, etc.

Referring to FIG. 3F, the device stack 300 may be patterned and etched to fabricate a plurality of memristor devices 300a, 300b, . . . , 300c. The etching of the layer 215 may form layers 315a, 315b, . . . , 315c of Ta metal. The etching of the first electrode 120 may form first electrodes 320a, 320b, . . . , 320c. The etching of the interface layer 330 may fabricate interface layers 330a, 330b, . . . , 330c. The etching of the switching oxide layer 340 may fabricate switching oxide layers 340a, 340b, . . . , 340c. The etching of the interface layer 350 may fabricate interface layers ILB 350a, 350b, . . . , 350c. The etching of the second electrode 360 may fabricate second electrodes 360a, 360b, . . . , 360c. The etching of the capping layer 370 may fabricate capping layers 370a, 370b, . . . , 370c. Each of the memristor devices 300a, 300b, . . . , 300c, may include a layer of Ta metal (layer 315a, 315b, . . . , 315c), a first electrode (first electrodes 320a, 320b, . . . , 320c), an oxide layer (oxide layers 340a, 340b, . . . , 340c), a second electrode (second electrodes 360a, 360b, . . . , 360c), an interface layer ILA (interface layers 330a, 330b, . . . , 330c) positioned between the first electrode and the switching oxide layer, and an interface layer ILB (interface layers 350a, 350b, . . . , 350c) positioned between the switching oxide layer and the second electrode. Each of the memristor devices 300a, 300b, . . . , 300c may further include a capping layer (capping layers 370a, 370b, . . . , 370c).

Due to the presence of the interface layers 330a-340c and 350a-330c, the drift switching may occur at specific locations where a second electrode 350a-350c is in direct contact with a switching oxide layer 340a-c, that is, the locations where the pin-holes in the interface layer ILB and the interface layer ILA directly contact a grain boundary in the switching oxide layer (e.g., grain boundaries 345a, 345b, and 345c). As such, the filaments can only form at the locations where the pin-holes in the interface layer directly contact a grain boundary in the switching oxide layer. The incorporation of the interface layers ILA and ILB may thus focus the electric field to specific locations within the device, reduce randomness in the drift switching, and minimize variations in filament location, size, or shape. As a result, cycle-to-cycle switch variations may be reduced, leading to more consistent synaptic switching.

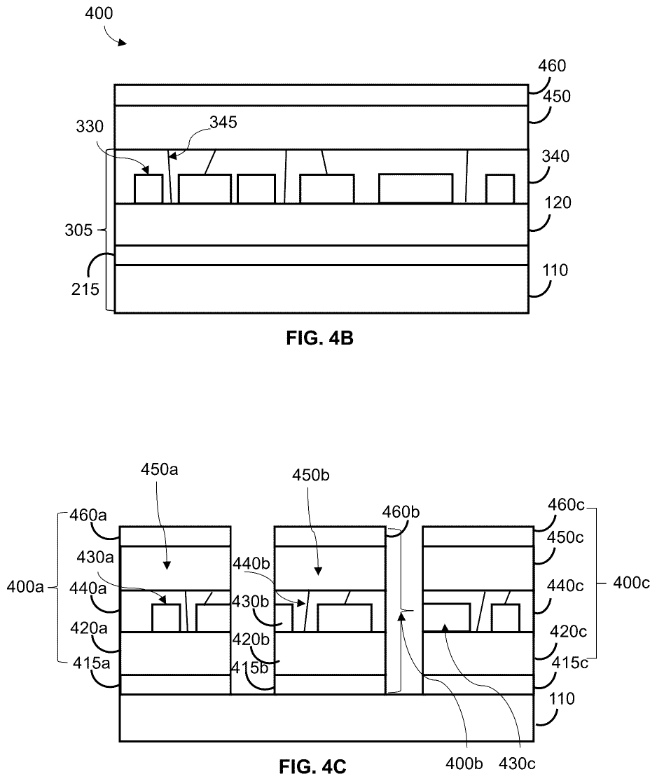

FIGS. 4A, 4B, and 4C are diagrams illustrating cross-sectional views of structures for fabricating semiconductor devices comprising memristor devices in accordance with another implementation of the present disclosure.

As shown in FIG. 4A, a second electrode 450 may be fabricated on the device stack 305 as depicted in FIG. 3B. In particular, the second electrode 450 may be fabricated on the switching oxide layer 340. The second electrode 450 may include any suitable material that is electronically conductive and may function as a source of metal ions during drift switching in the memristor devices to be fabricated. For example, the metallic material in the second electrode 450 may include Cu, Ag, etc. The second electrode 450 may also be referred to herein as an active electrode.

As shown in FIG. 4B, a capping layer 460 may be fabricated on the second electrode 450 to form a device stack 400. The capping layer 460 and the capping layer 370 in FIG. 3E may include the same similar materials and may perform the same or substantially the same functions.

As shown in FIG. 4C, the device stack 400 may be patterned and etched to fabricate a plurality of memristor devices 400a, 400b, . . . , 400c. Each of the memristor devices 400a, 400b, . . . , 400c may include a layer of Ta metal (e.g., layer 415a, 415b, . . . , 415c), a first electrode (e.g., electrode 420a, 420b, . . . , 420c), a switching oxide layer (e.g., switching oxide layer 440a, 440b, . . . , 440c), a second electrode (e.g., electrode 450a, 450b, . . . , 450c), an interface layer (e.g., interface layers 430a, 430b, . . . , 430c) positioned between the oxide layer and the first electrode, and/or a capping layer (e.g., capping layer 460a, 460b, . . . , 460c).

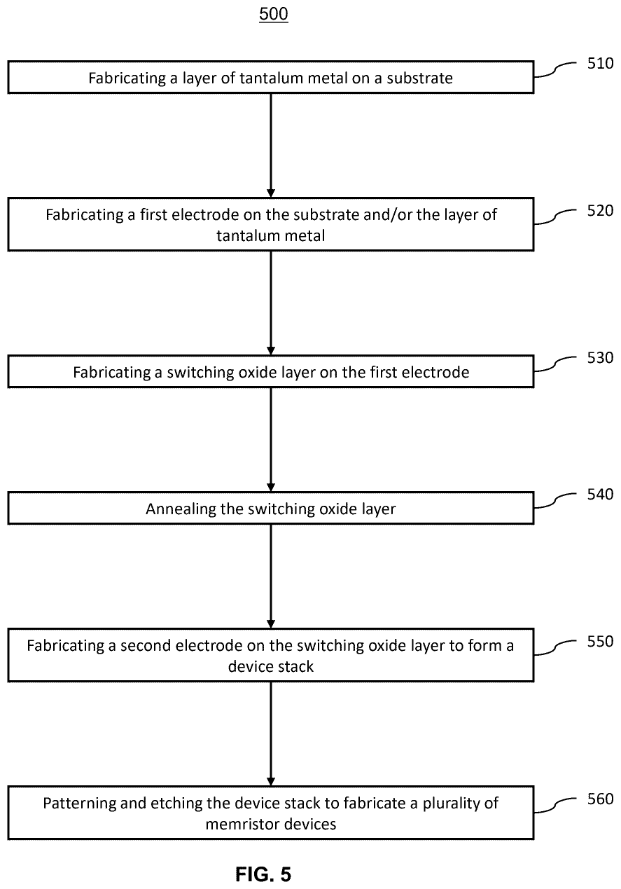

FIGS. 5, 6, 7, and 8 are flow diagrams illustrating example processes 500, 600, 700, and 800 for fabricating memristor devices in accordance with some embodiments of the present disclosure.

Referring to FIG. 5, process 500 may start at 510, where a layer of tantalum metal may be fabricated on a substrate. The layer of tantalum metal may be fabricated, for example, using physical vapor deposition (PVD), chemical vapor deposition (CVD), sputtering, etc. In some embodiments, block 510 may be omitted.

At 520, a first electrode may be fabricated on the substrate and/or the layer of tantalum metal. For example, a layer of a suitable electrically conductive material may be deposited utilizing atomic layer deposition (ALD), CVD, metal-organic chemical vapor deposition (MOCVD), PVD, molecular beam epitaxy (MBE) deposition, etc. The electrically conductive material may include, for example, Pt, Pd, Ir, W, Mo, Ru, etc. The first electrode may be the first electrode 120 as described in connection with FIG. 1A and FIG. 1B.

At 530, a switching oxide layer may be fabricated on the first electrode. The switching oxide layer may include one or more switching oxides. Each switching oxide may be a base oxide doped with at least one dopant. Examples of the base oxide may include tantalum pentoxide (Ta₂O₅), hafnium dioxide (HfO₂), zirconium dioxide (ZrO₂), niobium pentoxide (Nb₂O₅), vanadium pentoxide (V₂O₅), or silicon dioxide (SiO₂). The dopant may be one or more of copper (Cu), cuprous oxide (Cu2O), or cupric oxide (CuO). For example, the switching oxide layer may be fabricated by physical vapor deposition (PVD) co-deposition of a base oxide (e.g., hafnium dioxide) and a dopant (e.g., copper). As another example, the switching oxide layer may be fabricated by co-reactive deposition of a transition metal (e.g., tantalum (Ta), hafnium (Hf), zirconium (Zr), niobium (Nb), vanadium (V), etc.) and a metal dopant (e.g., copper). In some embodiments, the transition metal (e.g., hafnium) may be oxidized to form a metal oxide (e.g., hafnium dioxide), and the metal dopant (e.g., copper) may also be partially oxidized. The switching oxide layer may be the switching oxide layer 130 as described in connection with FIG. 1B.

At 540, the switching oxide layer may be annealed. The switching oxide layer may be annealed at a suitable temperature (e.g., 300° C.-500° C. for a suitable period of time (e.g., about 15-120 minutes). Annealing the switching oxide layer in a slightly oxidizing environment (e.g., an environment of argon (Ar) and oxygen (O₂)) may convert HfOₓ to HfO₂ and convert Cu to Cu₂O or CuO. In some embodiments, the switching oxide layer may be annealed at a later stage of the fabrication of the memristor devices (e.g., after step 550 and/or step 560).

At 550, a second electrode may be fabricated on the switching oxide layer. Fabricating the second electrode may involve depositing one or more metallic materials that may provide metal ions for drift switching of the memristor device to be fabricated. For example, fabricating the second electrode may involve depositing Cu and/or Ag using deposition processes such as PVD, electroplating, sputtering, etc. The second electrode may be the second electrode 140 as described in connection with FIG. 1C.

At 560, the device stack formed at 550 may be patterned and etched to fabricate a plurality of memristor devices, such as the memristor devices 170a, 170b, . . . , 170c of FIG. 1D.

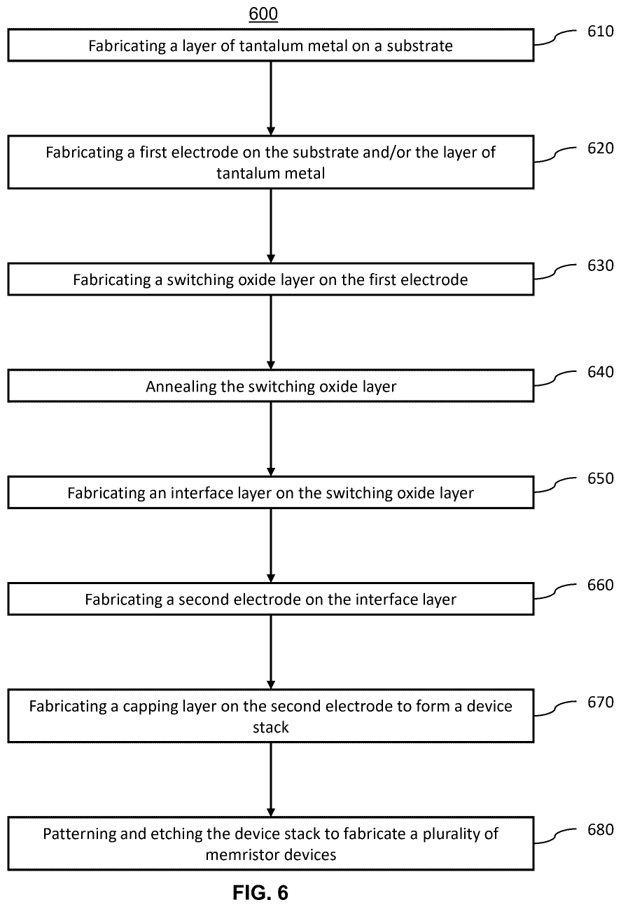

Referring to FIG. 6, process 600 may start at 610, where a layer of tantalum metal may be fabricated on a substrate. Blocks 610 and 510 may be performed in substantially the same manner.

At 620, a first electrode may be fabricated on the layer of tantalum metal and/or the substrate. Blocks 620 and 520 may be performed in substantially the same manner.

At 630, a switching oxide layer may be fabricated on the first electrode. Blocks 630 and 530 may be performed in substantially the same manner.

At 640, the switching oxide layer may be annealed. Blocks 640 and 540 may be performed in substantially the same manner. In some embodiments, block 640 may be performed after block 650, block 660, block 670, and/or block 680.

At 650, an interface layer may be fabricated on the switching oxide layer. The interface layer may include a discontinuous layer of a dielectric material. The interface layer may include a dielectric material that is more chemically stable than the dielectric oxide in the oxide layer and the electrode materials in the first electrode and/or the second electrode, such as Al₂O₃, Y₂O₃, MgO, etc. Fabricating the interface layer may involve depositing a discontinuous layer of the dielectric material, utilizing an ALD technique, a physical vapor deposition (PVD) technique, a reactive sputtering technique, and/or any other suitable deposition technique. The interface layer may be and/or include the interface layer 240 as described in connection with FIG. 2A above.

At 660, a second electrode may be fabricated on the interface layer and the switching oxide layer. Fabricating the second electrode may involve depositing one or more metallic materials that may provide metal ions for drift switching of the memristor device to be fabricated. For example, fabricating the second electrode may involve depositing Cu and/or Ag using deposition processes such as PVD, electroplating, sputtering, etc. As the interface layer includes a discontinuous layer of the dielectric material, at least a portion of the second electrode may be deposited on the switching oxide layer through the interface layer (e.g., through the pinholes in the discontinuous layer of the dielectric material). The second electrode may be the second electrode 250 as described in connection with FIG. 2B.

At 670, a capping layer may be fabricated on the second electrode to fabricate a device stack. Fabricating the capping layer may involve depositing Ta, TaN, W, WN, etc. using deposition techniques such as sputtering, CVD, ALD, etc. The capping layer may be the capping layer 260 as described in connection with FIG. 2C above. The device stack may be the device stack 200c of FIG. 2C.

At 680, the device stack may be patterned and etched to fabricate a plurality of memristor devices, such as the memristor devices 2000a, 2000b, . . . , 2000c of FIG. 2D or memristor devices 270a, 270b, . . . , 270c of FIG. 2G.

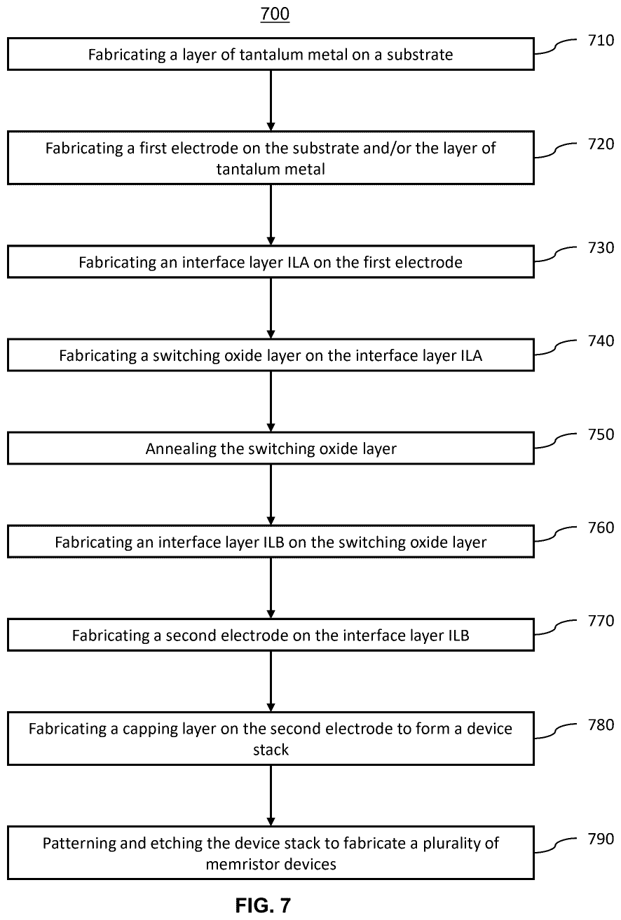

Referring to FIG. 7, process 700 may start at 710, where a layer of tantalum metal may be fabricated on a substrate. Blocks 710 and 510 may be performed in substantially the same manner.

At 720, a first electrode may be fabricated on the substrate and/or the layer of tantalum metal. Blocks 720 and 520 may be performed in substantially the same manner.

At 730, an interface layer ILA may be fabricated on the first electrode. Fabricating the interface layer ILA may involve depositing a discontinuous layer of a dielectric material that is more chemically stable than the dielectric oxide in the oxide layer and the electrode materials in the first electrode and/or the second electrode, such as Al₂O₃, Y₂O₃, MgO, etc. In some embodiments, the dielectric material may be deposited on the first electrode to a suitable thickness to form a discontinuous film of the dielectric material. The dielectric material may be deposited utilizing an ALD technique, a PVD technique, reactive sputtering, and/or any other suitable deposition technique. The interface layer ILA may be the interface layer 330 as described in connection with FIG. 3A.

At 740, a switching oxide layer may be fabricated on the first electrode and the interface layer ILA. The switching oxide layer may include one or more switching oxides. Each switching oxide may be a base oxide doped with at least one dopant. Examples of the base oxide may include Ta₂O₅, HfO₂, ZrO₂, Nb₂O₅, V₂O₅, SiO₂, etc. The dopant may be one or more of Cu, Cu₂O, CuO, etc. For example, the switching oxide layer may be fabricated by PVD co-deposition of a base oxide (e.g., hafnium dioxide) and a dopant (e.g., copper). As another example, the switching oxide layer may be fabricated by co-reactive deposition of a transition metal (e.g., Ta, Hf, Zr, Nb, V, etc, and a metal dopant (e.g., copper). In some embodiments, the transition metal (e.g., hafnium) may be oxidized to form a metal oxide (e.g., hafnium dioxide), and the metal dopant (e.g., copper) may also be partially oxidized. The switching oxide layer may be the switching oxide layer 340 as described in connection with FIG. 3B. As the interface layer ILA contains a discontinuous layer of the first dielectric material, one or more portions of the switching oxide layer may be deposited on the first electrode through the pin-holes/pores of the interface layer ILA and directly contact the first electrode through the interface layer ILA (through the pin-holes or pores of the interface layer ILA).

At 750, the switching oxide layer may be annealed. Blocks 750 and 540 may be performed in substantially the same manner. In some embodiments, block 750 may be performed after block 760, block 770, block 780, and/or block 790.

At 760, an interface layer ILB may be fabricated on the switching oxide layer. The interface layer ILB may be the interface layer 350 as described in connection with FIG. 3C. Blocks 760 and 650 may be performed in substantially the same manner.

At 770, a second electrode may be fabricated on the interface layer ILB and the oxide layer. The second electrode may be the second electrode 360 of FIG. 3D. Blocks 770 and 660 may be performed in substantially the same manner.

At 780, a capping layer may be fabricated on the second electrode to form a device stack. The capping layer may be the capping layer 370 as described in connection with FIG. 3E above. Blocks 780 and 670 may be performed in substantially the same manner. The device stack may be the device stack 300 as described in connection with FIG. 3E.

At 790, the device stack may be patterned and etched to fabricate a plurality of memristor devices (e.g., memristor devices 300a, 300b, . . . , 300c, as shown in FIG. 3F).

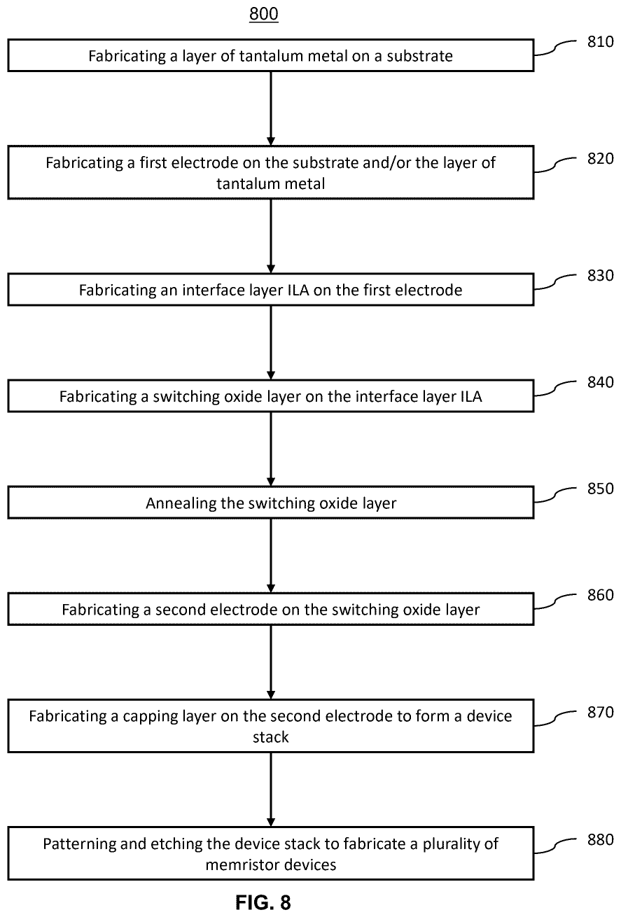

Referring to FIG. 8, process 800 may start at 810, where a layer of tantalum metal may be fabricated on a substrate. Blocks 810 and 510 may be performed in substantially the same manner.

At 820, a first electrode may be fabricated on the substrate and/or the layer of tantalum metal. Blocks 820 and 520 may be performed in substantially the same manner.

At 830, an interface layer may be fabricated on the first electrode. Fabricating the interface layer (also referred to as the interface layer ILA) may involve depositing a discontinuous layer of a dielectric material that is more chemically stable than the dielectric oxide in the oxide layer and the electrode materials in the first electrode and/or the second electrode, such as Al₂O₃, Y₂O₃, MgO, etc. In some embodiments, the dielectric material may be deposited on the first electrode to a suitable thickness to form a discontinuous film of the dielectric material. The dielectric material may be deposited utilizing an ALD technique, a PVD technique, reactive sputtering, and/or any other suitable deposition technique. Blocks 830 and 730 may be performed in substantially the same manner. The interface layer ILA may be the interface layer 330 as described in connection with FIG. 4A.

At 840, a switching oxide layer may be fabricated on the first electrode and the interface layer ILA. Blocks 840 and 740 may be performed in substantially the same manner. The switching oxide layer may be the switching oxide layer 340 as described in connection with FIG. 4A.

At 850, the switching oxide layer may be annealed. Blocks 850 and 540 may be performed in substantially the same manner. In some embodiments, block 850 may be performed after block 860, block 870, and/or block 880.

At 860, a second electrode may be fabricated on the switching oxide layer. Fabricating the second electrode may involve depositing one or more metallic materials on the oxide layer. The metallic materials may provide metal ions for drift switching of the memristor device to be fabricated. For example, fabricating the second electrode may involve depositing Cu and/or Ag using deposition processes such as PVD, electroplating, sputtering, etc. The second electrode may be the second electrode 450 of FIG. 4A.

At 870, a capping layer may be fabricated on the second electrode to form a device stack. The capping layer may be the capping layer 460 as described in connection with FIG. 4B above. Blocks 870 and 670 may be performed in substantially the same manner. The device stack may be the device stack 400 as described in connection with FIG. 4B.

At 880, the device stack may be patterned and etched to fabricate a plurality of memristor devices (e.g., memristor devices 400a, 400b, . . . , 400c, as shown in FIG. 4C).

For simplicity of explanation, the methods of this disclosure are depicted and described as a series of acts. However, acts in accordance with this disclosure can occur in various orders and/or concurrently, and with other acts not presented and described herein. Furthermore, not all illustrated acts may be required to implement the methods in accordance with the disclosed subject matter. In addition, those skilled in the art will understand and appreciate that the methods could alternatively be represented as a series of interrelated states via a state diagram or events.

The terms “approximately,” “about,” and “substantially” as used herein may mean within a range of normal tolerance in the art, such as within 2 standard deviations of the mean, within ±20% of a target dimension in some embodiments, within ±10% of a target dimension in some embodiments, within ±5% of a target dimension in some embodiments, within ±2% of a target dimension in some embodiments, within ±1% of a target dimension in some embodiments, and yet within ±0.1% of a target dimension in some embodiments. The terms “approximately” and “about” may include the target dimension. Unless specifically stated or obvious from context, all numerical values described herein are modified by the term “about.”

As used herein, a range includes all the values within the range. For example, a range of 1 to 10 may include any number, combination of numbers, sub-range from the numbers of 1, 2, 3, 4, 5, 6, 7, 8, 9, and 10 and fractions thereof.

In the foregoing description, numerous details are set forth. It will be apparent, however, that the disclosure may be practiced without these specific details. In some instances, well-known structures and devices are shown in block diagram form, rather than in detail, in order to avoid obscuring the disclosure.

The terms “first,” “second,” “third,” “fourth,” etc. as used herein are meant as labels to distinguish among different elements and may not necessarily have an ordinal meaning according to their numerical designation.

The words “example” or “exemplary” are used herein to mean serving as an example, instance, or illustration. Any aspect or design described herein as “example” or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or”. That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Reference throughout this specification to “an implementation” or “one implementation” means that a particular feature, structure, or characteristic described in connection with the implementation is included in at least one implementation. Thus, the appearances of the phrase “an implementation” or “one implementation” in various places throughout this specification are not necessarily all referring to the same implementation.

As used herein, when an element or layer is referred to as being “on” another element or layer, the element or layer may be directly on the other element or layer, or intervening elements or layers may be present. In contrast, when an element or layer is referred to as being “directly on” another element or layer, there are no intervening elements or layers present.

Whereas many alterations and modifications of the disclosure will no doubt become apparent to a person of ordinary skill in the art after having read the foregoing description, it is to be understood that any particular embodiment shown and described by way of illustration is in no way intended to be considered limiting. Therefore, references to details of various embodiments are not intended to limit the scope of the claims, which in themselves recite only those features regarded as the disclosure.

What is claimed is:

1. A semiconductor device, comprising:
a memristor device, comprising:
a first electrode;
a switching oxide layer fabricated on the first electrode, wherein the switching oxide layer comprises at least one base oxide doped with at least one dopant; and
a second electrode fabricated on the switching oxide layer.

2. The semiconductor device of claim 1, wherein the base oxide comprises at least one of silicon dioxide (SiO₂), hafnium dioxide (HfO₂), tantalum pentoxide (Ta₂O₅), zirconium dioxide (ZrO₂), niobium pentoxide (Nb₂O₅), vanadium pentoxide (V₂O₅), and wherein the at least one dopant comprises at least one of copper (Cu), cuprous oxide (Cu₂O), or cupric oxide (CuO).

3. The semiconductor device of claim 2, wherein the first electrode comprises at least one of platinum (Pt), palladium (Pd), iridium (Ir), tungsten (W), molybdenum (Mo), or ruthenium (Ru).

4. The semiconductor device of claim 3, wherein the second electrode comprises at least one of Cu or Ag.

5. The semiconductor device of claim 1, further comprising a first interface layer fabricated between the switching oxide layer and the second electrode, wherein the first interface layer comprises a first dielectric material, and wherein the first dielectric material comprises at least one of Al₂O₃, Y₂O₃, or MgO.

6. The semiconductor device of claim 5, wherein the first interface layer comprises a discontinuous layer of the first dielectric material, and wherein at least a portion of the second electrode is deposited on the switching oxide layer through the discontinuous layer of the first dielectric material.

7. The semiconductor device of claim 6, wherein the memristor device comprises a second interface layer fabricated between the first electrode and the switching oxide layer, wherein the second interface layer comprises a second dielectric material.

8. The semiconductor device of claim 7, wherein the second dielectric material comprises at least one of Al₂O₃, Y₂O₃, or MgO, and wherein the second interface layer comprises a discontinuous layer of the second dielectric material, and wherein at least a portion of the switching oxide layer is deposited on the first electrode through the second interface layer.

9. The semiconductor device of claim 1, further comprising a capping layer fabricated on the second electrode, wherein the capping layer comprises a metal or a metal nitride.

10. The semiconductor device of claim 1, further comprising a layer of tantalum deposited between the first electrode and a substrate.

11. A method for fabricating a memristor device, comprising:
fabricating, on a first electrode, a switching oxide layer comprising at least one base oxide doped with at least one dopant;
annealing the switching oxide layer; and
fabricating a second electrode on the annealed switching oxide layer.

12. The method of claim 11, wherein the base oxide comprises at least one of silicon dioxide (SiO₂), hafnium dioxide (HfO₂), tantalum pentoxide (Ta₂O₅), zirconium dioxide (ZrO₂), niobium pentoxide (Nb₂O₅), vanadium pentoxide (V₂O₅), and wherein the at least one dopant comprises at least one of copper (Cu), cuprous oxide (Cu₂O), or cupric oxide (CuO).

13. The method of claim 12, wherein the first electrode comprises at least one of platinum (Pt), palladium (Pd), iridium (Ir), tungsten (W), molybdenum (Mo), or ruthenium (Ru).

14. The method of claim 13, wherein the second electrode comprises a metallic material for providing metal ions during drift switching of the memristor device, wherein the metallic material comprises at least one copper (Cu) or silver (Ag).

15. The method of claim 11, further comprising fabricating a first interface layer positioned between the switching oxide layer and the second electrode, wherein the first interface layer comprises a discontinuous layer of a first dielectric material, and wherein fabricating the second electrode comprises depositing at least a metallic material on the switching oxide layer through the discontinuous layer of the first dielectric material.

16. The method of claim 15, further comprising fabricating, on the first electrode, a second interface layer comprising a second dielectric material, wherein the switching oxide layer is fabricated on the second interface layer.

17. The method of claim 16, wherein the second dielectric material comprises at least one of Al₂O₃, Y₂O₃, or MgO, and wherein the second interface layer comprises a discontinuous layer of the second dielectric material, and wherein at least a portion of the switching oxide layer is deposited on the first electrode through the second interface layer.

18. The method of claim 17, further comprising fabricating a capping layer on the second electrode, wherein the capping layer comprises at least one of a metal or a metal nitride.

19. The method of claim 11, further comprising depositing a layer of tantalum metal on a substrate, wherein the first electrode is fabricated on the layer of tantalum metal.

20. The method of claim 11, wherein the switching oxide layer is annealed in an environment of argon (Ar) and oxygen (O₂).
